(19) United States
(12) Patent Application Publication
(10) Pub. No.: US 2026/0215230 A1
(43) Pub. Date: Jul. 23, 2026

(54) SEMICONDUCTOR DEVICES AND DATA STORAGE SYSTEMS INCLUDING THE SAME

(71) Applicant: SAMSUNG ELECTRONICS CO., LTD., Suwon-si (KR)

(72) Inventors: Yerin CHOI, Suwon-si (KR); Kyounghoon KIM, Suwon-si (KR); Jeeyun LEE, Suwon-si (KR)

(73) Assignee: SAMSUNG ELECTRONICS CO., LTD., Suwon-si (KR)

(21) Appl. No.: 19/287,022

(22) Filed: Jul. 31, 2025

(30) Foreign Application Priority Data
Jan. 17, 2025 (KR) 10-2025-0007298

(51) Int. Cl. H10P 74/00; H10B 80/00; H10W 90/00; H10W 80/00; H10W 90/20

(52) U.S. Cl. CPC H10P 74/273; H10B 80/00; H10W 90/00; H10W 80/312; H10W 80/327; H10W 90/284; H10W 90/792

(57) ABSTRACT

A semiconductor device includes a first substrate structure including a substrate, circuit elements on the substrate in a chip region, a circuit interconnection structure on the circuit elements, a circuit test element in a test element region, a first test interconnection structure in the test element region and electrically connected to the circuit test element, and first bonding pads on the circuit interconnection structure and the first test interconnection structure, and a second substrate structure on the first substrate structure. The second substrate structure includes gate electrodes, a channel structure penetrating the gate electrodes, a cell interconnection structure electrically connected to the channel structure and the gate electrodes, a cell test element in the test element region, a second test interconnection structure in the test element region and electrically connected to the cell test element and electrically isolated from the first test interconnection structure, and second bonding pads.

### CROSS-REFERENCE TO RELATED APPLICATIONS

This application claims the benefit under 35 USC 119(a) of Korean Patent Application No. 10-2025-0007298 filed on January 17, 2025 in the Korean Intellectual Property Office, the entire disclosure of which is incorporated herein by reference for all purposes.

### BACKGROUND

The present inventive concept relates to semiconductor devices and data storage systems including the same.

A semiconductor device may be formed by performing a series of unit processes including a deposition process for depositing a thin film on a semiconductor substrate, a photolithography process for patterning the thin film, an etching process, and the like. To confirm whether the semiconductor elements are formed to conform to the design of the semiconductor device, after part or all of the unit processes are completed, the presence or absence of defects in the semiconductor elements constituting the semiconductor device may be inspected, and the electrical characteristics of the semiconductor elements may be evaluated. To evaluate the characteristics of the semiconductor elements, measuring elements or test elements may be formed together with the semiconductor elements. The semiconductor substrate may include chip regions on which integrated circuits are formed and scribe lanes between the chip regions, and the test elements may generally be formed on the scribe lanes of the semiconductor substrate.

### SUMMARY

Example embodiments provide semiconductor devices having improved utilization of a scribe lane and a data storage system including the same.

According to example embodiments, a semiconductor device includes a first substrate structure including a substrate, circuit elements on the substrate in a chip region, a circuit interconnection structure on the circuit elements, a circuit test element in a test element region, spaced from the chip region, a first test interconnection structure in the test element region and electrically connected to the circuit test element, and first bonding pads on the circuit interconnection structure and the first test interconnection structure; and a second substrate structure on the first substrate structure. The second substrate structure includes gate electrodes stacked while being spaced apart from each other in a first direction, perpendicular to an upper surface of the substrate in the chip region; a channel structure penetrating the gate electrodes; a cell interconnection structure electrically connected to the channel structure and the gate electrodes; a cell test element in the test element region; a second test interconnection structure in the test element region and electrically connected to the cell test element, and electrically isolated from the first test interconnection structure; and second bonding pads below the cell interconnection structure and the second test interconnection structure and bonded to the first bonding pads respectively.

According to example embodiments, a semiconductor device includes a first substrate structure including a substrate, a circuit test element on the substrate, and a first test interconnection structure electrically connected to the circuit test element; and a second substrate structure on the first substrate structure, the second substrate structure including a cell test element including test gate electrodes spaced apart from each other and stacked in a first direction, perpendicular to an upper surface of the substrate and a test channel structure penetrating the test gate electrodes, and a second test interconnection structure electrically connected to one of the test gate electrodes and the test channel structure. The second test interconnection structure overlaps the first test interconnection structure in the first direction and is spaced apart from the first test interconnection structure.

According to example embodiments, a data storage system includes a semiconductor storage device including a first substrate structure including a substrate and circuit elements on the substrate, a second substrate structure on the first substrate structure, and an input/output pad electrically connected to the circuit elements; and a controller electrically connected to the semiconductor storage device through the input/output pad and configured to control the semiconductor storage device. The first substrate structure further includes a circuit test structure disposed to be spaced apart from the circuit elements. The second substrate structure includes memory cells, vias below the memory cells and electrically connected to the memory cells, and a cell test structure spaced apart from the memory cells to one side. The cell test structure is stacked on the circuit test structure and spaced apart from the circuit test structure at a level of the vias.

### BRIEF DESCRIPTION OF DRAWINGS

The above and other aspects, features, and advantages of the present inventive concept will be more clearly understood from the following detailed description, taken in conjunction with the accompanying drawings, in which:

FIGS. 1A and 1B are schematic plan views of a semiconductor device according to example embodiments;

FIG. 2 is a schematic perspective view of a semiconductor device according to example embodiments;

FIGS. 3A and 3B are schematic cross-sectional views of a semiconductor device according to example embodiments;

FIG. 4 is a cross-sectional view of a semiconductor device according to example embodiments;

FIG. 5 is a flow chart illustrating a method of measuring a semiconductor device according to example embodiments;

FIG. 6 is a schematic perspective view of a semiconductor device according to example embodiments;

FIGS. 7A to 7G are schematic cross-sectional views illustrating a method of manufacturing a semiconductor device according to example embodiments; and

FIG. 8 is a schematic drawing of a data storage system including a semiconductor device according to example embodiments.

### DETAILED DESCRIPTION

Hereinafter, example embodiments will be described with reference to the accompanying drawings.

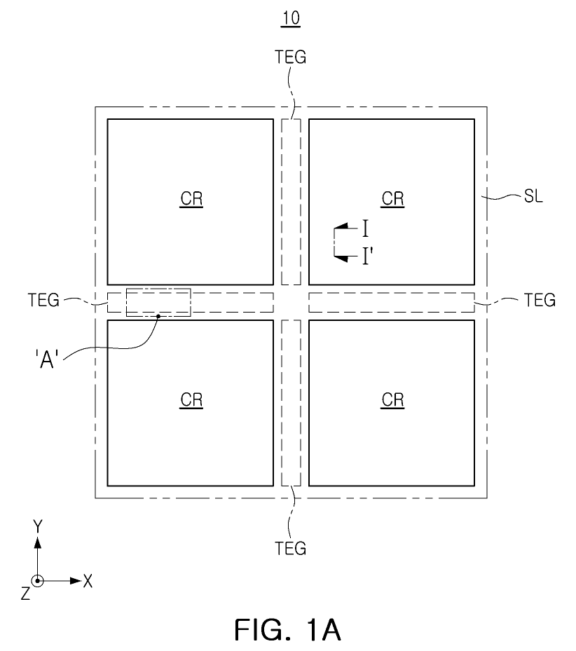

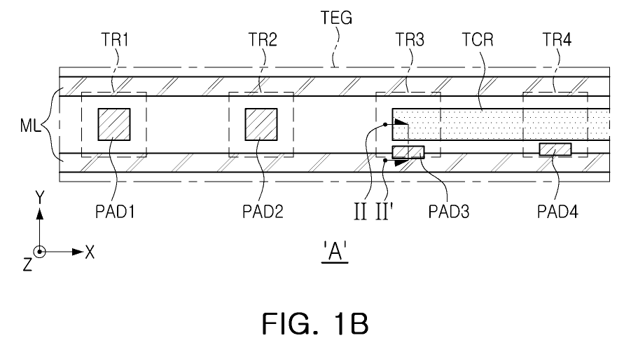

FIGS. 1A and 1B are schematic plan views of a semiconductor device according to example embodiments. FIG. 1B illustrates an enlarged view of a region ‘A’ of FIG. 1A.

Referring to FIG. 1A, a semiconductor device 10 may include chip regions CR and scribe lanes SL surrounding the respective chip regions CR.

The scribe lanes SL may be regions for performing a dicing process along the scribe lanes on a wafer on which the semiconductor device 10 is formed. The scribe lanes SL may be removed or partially remain after the dicing process. The scribe lanes SL may include test element groups TEGs. However, the arrangement positions and shapes of the test element groups TEGs within the scribe lanes SL may be variously changed in example embodiments.

Each of the chip regions CRs may include a memory semiconductor chip and/or a logic semiconductor chip. The memory semiconductor chip may be a volatile memory such as a dynamic random access memory (DRAM), a static random access memory (SRAM), or a nonvolatile memory such as a NAND flash memory. The logic semiconductor chip may be a microprocessor, for example, a central processing unit (CPU), a graphics processing unit (GPU), a field programmable gate array (FPGA), an application processor (AP), a digital signal processor, an encryption processor, a controller, or an application specific integrated circuit (ASIC). For example, each of the chip regions CR may include a NAND element.

Referring to FIG. 1B, an example embodiment of the test element group TEG of FIG. 1A is illustrated. The test element group TEG may include a test cell array region TCR and first to fourth test element regions TR1, TR2, TR3 and TR4 that are spaced apart from each other.

The test cell array region TCR may include a cell test element having a structure corresponding to the chip regions CR of FIG. 1A. The cell test element may include, for example, a memory cell array structure. The test cell array region TCR may be disposed to overlap the third and fourth test element regions TR3 and TR4. However, in some embodiments, the test cell array region TCR may be disposed within each of the first to fourth test element regions TR1, TR2, TR3 and TR4, or may be disposed in regions between the first to fourth test element regions TR1, TR2, TR3 and TR4.

The first to fourth test element regions TR1, TR2, TR3 and TR4 may be regions for testing different electrical characteristics of the cell test element disposed in the test cell array region TCR. The respective first to fourth test element regions TR1, TR2, TR3 and TR4 may be electrically connected to the cell test element of the test cell array region TCR through interconnection lines ML. In addition, the first to fourth test element regions TR1, TR2, TR3 and TR4 may be regions for testing electrical characteristics of circuit test elements disposed in the respective first to fourth test element regions TR1, TR2, TR3 and TR4.

The first to fourth test element regions TR1, TR2, TR3 and TR4 may further include first to fourth pad regions PAD1, PAD2, PAD3 and PAD4, respectively. The first to fourth pad regions PAD1, PAD2, PAD3 and PAD4 may be regions connected to a test facility for testing electrical characteristics, and may include, for example, pad conductive layers connected to a probe of the test facility.

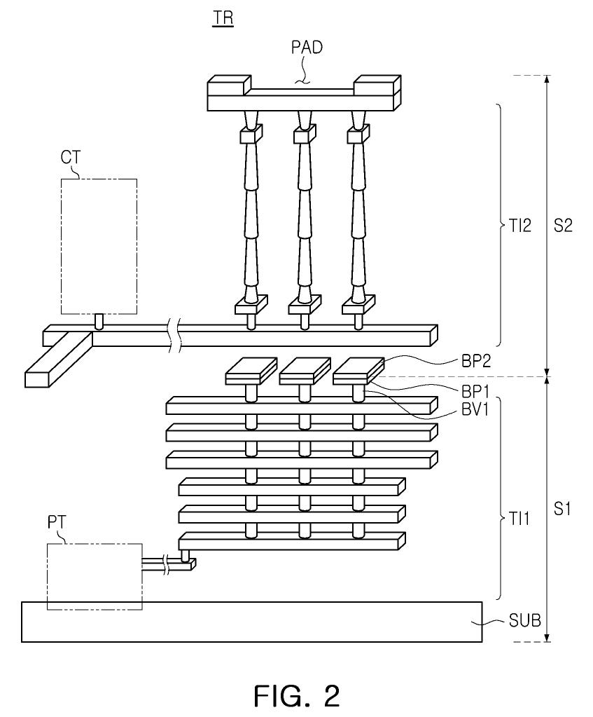

FIG. 2 is a schematic perspective view of a semiconductor device according to example embodiments.

Referring to FIG. 2, a structure of a test element region TR is schematically illustrated. The test element region TR may correspond to each of the first to fourth test element regions TR1, TR2, TR3 and TR4 of FIG. 1B. The test element region TR may include first and second substrate structures S1 and S2 that are vertically bonded.

The first substrate structure S1 may include a substrate SUB, a circuit test element PT on the substrate SUB, and a first test interconnection structure TI1 electrically connected to the circuit test element PT. The circuit test element PT and the first test interconnection structure TI1 may form a circuit test structure. The first substrate structure S1 may further include first bonding vias BV1 and first bonding pads BP1 that are bonding structures.

The circuit test element PT may include elements for predicting electrical characteristics of circuit elements disposed in the chip region CR (see FIG. 1A). For example, the circuit test element PT may include elements such as transistors, resistors, capacitors, or inductors corresponding to the circuit elements.

The first test interconnection structure TI1 may at least partially overlap the pad region PAD vertically. The first test interconnection structure TI1, the first bonding vias BV1, and the first bonding pads BP1 may be electrically connected to the circuit test element PT. In this specification, ‘electrically connected’ may mean a case where an electrical path is formed between the components, regardless of whether an electrical signal is actually applied from the outside. The second bonding pads BP2 that are bonded to the first bonding pads BP1 may also be electrically connected to the circuit test element PT.

The second substrate structure S2 may be disposed on the first substrate structure S1 and may include a cell test element CT and a second test interconnection structure TI2 electrically connected to the cell test element CT. The cell test element CT and the second test interconnection structure TI2 may form a cell test structure. The second substrate structure S2 may further include second bonding pads BP2 as bonding structures and a pad region PAD for connection to a test facility.

The cell test element CT may include an element for predicting electrical characteristics of a semiconductor element disposed in a chip region CR, for example, a memory cell array structure. For example, the cell test element CT may include an element composed of a test memory cell array structure disposed in a test cell array region TCR of FIG. 1B. As described above with reference to FIG. 1B, in some embodiments, the cell test element CT may be positioned so as not to be physically adjacent to the second test interconnection structure TI2. In example embodiments, the cell test element CT may or may not vertically overlap the circuit test element PT. However, at least a portion of the cell test structure may vertically overlap the circuit test structure.

The second test interconnection structure TI2 may be electrically connected to the cell test element CT. The second test interconnection structure TI2 may be electrically isolated from the first test interconnection structure TI1 and may also be electrically isolated from the second bonding pads BP2. The second test interconnection structure TI2 may be electrically isolated from the first test interconnection structure TI1, for example, by omitting the second bonding vias on the second bonding pads BP2. The second test interconnection structure TI2 may at least partially overlap vertically with the first test interconnection structure TI1.

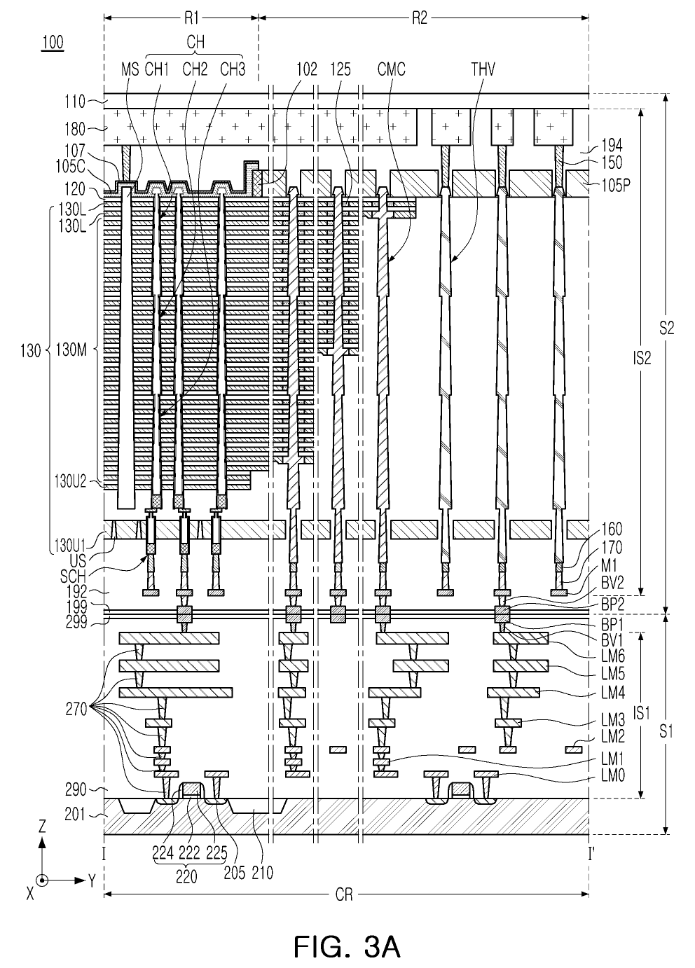

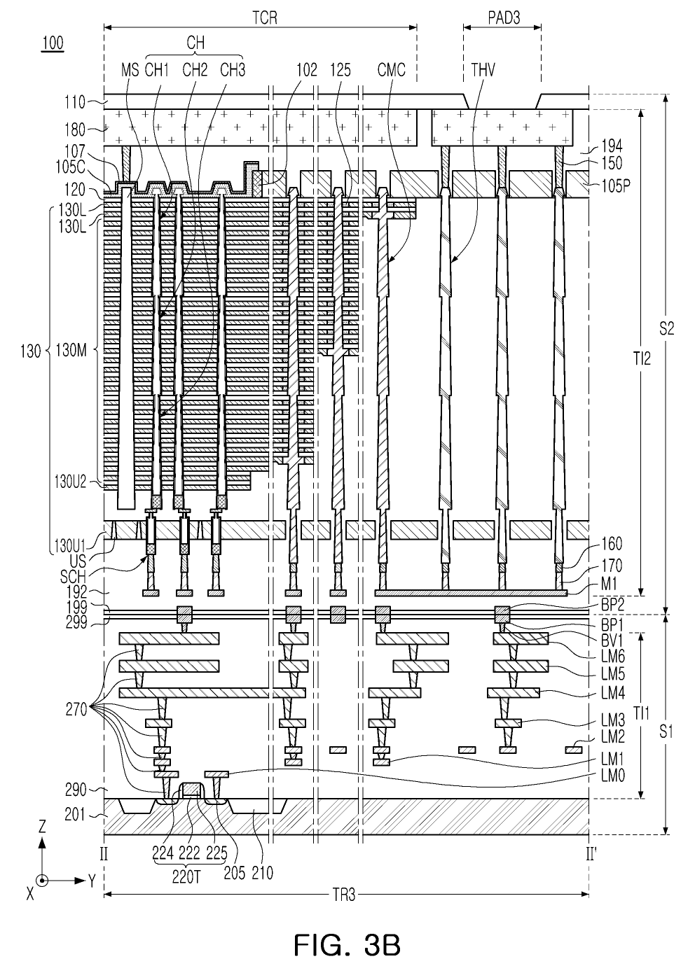

FIGS. 3A and 3B are schematic cross-sectional views of a semiconductor device according to example embodiments. FIG. 3A illustrates a cross-section along the cutting line I-I’ of FIG. 1A, and FIG. 3B illustrates a cross-section along the cutting line II-II’ of FIG. 1B.

Referring to FIGS. 3A and 3B, a semiconductor device 100 includes first and second substrate structures S1 and S2 that are bonded vertically. The first substrate structure S1 may include a peripheral circuit region, and the second substrate structure S2 may include a memory cell region. In some embodiments, the second semiconductor structure S2 may be disposed below the first semiconductor structure S1.

The first substrate structure S1 may include a substrate 201, source/drain regions 205 and element isolation layers 210 within the substrate 201, circuit elements 200 and a test circuit gate structure 220T disposed on the substrate 201, a peripheral insulating layer 290, circuit contact plugs 270, circuit interconnection lines LM0, LM1, LM2, LM3, LM4, LM5 and LM6, first bonding vias BV1, first bonding pads BP1, and a first bonding insulating layer 299.

The substrate 201 may have an upper surface extending in the X direction and the Y direction. An active region may be defined by the element isolation layers 210 in the substrate 201. Source/drain regions 205 including impurities may be disposed in a portion of the active region. The substrate 201 may include a semiconductor material, such as a group IV semiconductor, a group III-V compound semiconductor, or a group II-VI compound semiconductor. The substrate 201 may be provided as a bulk wafer or an epitaxial layer.

The circuit gate structures 220 and the test circuit gate structure 220T may form planar transistors. Each of the circuit gate structures 220 and the test circuit gate structure 220T may include a circuit gate dielectric layer 222, a spacer layer 224, and a circuit gate electrode 225. Source/drain regions 205 may be disposed as source/drain regions within the substrate 201 on both sides of the circuit gate electrode 225. The circuit gate structures 220 may form circuit elements together with the source/drain regions 205, and the test circuit gate structure 220T may form test circuit elements together with the source/drain regions 205. In the present embodiment, the test circuit gate structure 220T may have a structure corresponding to at least one of the circuit gate structures 220, for example, a structure that is identical or only different in scale, but the specific form of the test circuit gate structure 220T is not limited thereto.

The peripheral insulating layer 290 may be disposed to cover the circuit gate structures 220 and the test circuit gate structure 220T on the upper surface of the substrate 201. The peripheral insulating layer 290 may include a plurality of insulating layers formed in different process stages. The peripheral insulating layer 290 may be made of an insulating material.

The circuit contact plugs 270 and the circuit interconnection lines LM0, LM1, LM2, LM3, LM4, LM5 and LM6 may form a first interconnection structure IS1 electrically connected to the circuit gate structures 220 and the source/drain regions 205, and a first test interconnection structure TI1 electrically connected to the test circuit gate structures 220T and the source/drain regions 205. The first interconnection structure IS1 may also be referred to as a circuit interconnection structure, or the like. The first interconnection structure IS1 and the first test interconnection structure TI1 may be physically and electrically separated from each other.

The circuit contact plugs 270 may have a cylindrical shape, and the circuit interconnection lines LM0, LM1, LM2, LM3, LM4, LM5 and LM6 may have a line shape. In the chip region CR, an electrical signal may be applied to the circuit element by the circuit contact plugs 270 and the circuit interconnection lines LM0, LM1, LM2, LM3, LM4, LM5 and LM6. In a region not illustrated, the circuit contact plugs 270 may also be connected to the circuit gate electrode 225. The circuit interconnection lines LM0, LM1, LM2, LM3, LM4, LM5 and LM6 may be connected to the circuit contact plugs 270 and may be disposed in multiple layers. The circuit contact plugs 270 and the circuit interconnection lines LM0, LM1, LM2, LM3, LM4, LM5 and LM6 may include a conductive material, for example, tungsten (W), copper (Cu), aluminum (Al), or the like, and each of the configurations may further include a diffusion barrier. In example embodiments, the number of layers of the circuit contact plugs 270 and the circuit interconnection lines LM0, LM1, LM2, LM3, LM4, LM5 and LM6 may vary.

The first bonding vias BV1, the first bonding pads BP1, and the first bonding insulating layer 299 constitute a first bonding structure and may be disposed on the uppermost circuit interconnection lines LM6. The first bonding vias BV1 may have a cylindrical shape, and the first bonding pads BP1 may have a pad shape having a circular shape on a plane or a relatively short line shape. The upper surfaces of the first bonding pads BP1 may form a portion of the upper surface of the first substrate structure S1. In the chip region CR, the first bonding vias 295 and a first bonding pads 298 may provide an electrical connection path with the second semiconductor structure S2. In some embodiments, some of the first bonding pads BP1 may not be connected to the circuit interconnection lines LM0, LM1, LM2, LM3, LM4, LM5 and LM6 and may be disposed only for bonding. The first bonding vias BV1 and the first bonding pads BP1 may include a conductive material, for example, copper (Cu).

The first bonding insulating layer 299 may be disposed on the upper surface of the peripheral insulating layer 290 with a predetermined thickness. The first bonding insulating layer 299 may be a layer for dielectric-dielectric bonding with a second bonding insulating layer 199 of the second semiconductor structure S2. The first bonding insulating layer 299 may also function as a diffusion barrier of the first bonding pads BP1 and may include, for example, at least one of SiO, SiN, SiCN, SiOC, SiON, or SiOCN.

The second substrate structure S2 may include vertically stacked gate electrodes 130, interlayer insulating layers 120 alternately stacked with the gate electrodes 130, first channel structures CH penetrating portions of the gate electrodes 130, second channel structures SCH respectively connected to the first channel structures CH, first and second source layers 105C and 107 on the upper ends of the first channel structures CH, first separation regions MS extending by penetrating through the gate electrodes 130, second separation regions US penetrating a first upper gate electrode 130U1 disposed at the lower portion among the gate electrodes 130, first and second cell region insulating layers 192 and 194, a second interconnection structure IS2, and a second test interconnection structure TI2. The second substrate structure S2 may further include a dam structure 102, an upper semiconductor layer 105P, a pad insulating layer 110, contact insulating layers 125, second bonding vias BV2, second bonding pads BP2, and a second bonding insulating layer 199.

The second substrate structure S2 may include first and second regions R1, R2 in the chip region CR. The first region R1 may be a region where gate electrodes 130 are vertically stacked and first channel structures CH are disposed, and may be a region where memory cells are disposed. The second region R2 may be a region where gate electrodes 130 are extended to different lengths to form gate pad regions, and may correspond to a region for electrically connecting the memory cells to the circuit gate structures 220 of the first substrate structure S1. The second region R2 may be disposed at least on one end of the first region R1, at least in one direction, for example, in the Y direction.

The second substrate structure S2 may include a test cell array region TCR and a third pad region PAD3 in the third test element region TR3. The test cell array region TCR may be a region in which a memory cell array structure corresponding to the chip region CR is disposed. For example, the memory cell array structure of the test cell array region TCR may have the same structure as the memory cell array structure of the chip region CR, but may have a smaller size than the memory cell array structure of the chip region CR, and for example, the area of the gate electrodes 130 on the plane may be relatively small and thus the number of the first and second channel structures CH and SCH may be relatively small. In addition, unlike the memory cell array structure of the chip region CR, the memory cell array structure of the test cell array region TCR may not include a second bonding via BV2. This is explained in more detail below.

The gate electrodes 130 may be stacked in a direction spaced apart from each other in a direction, perpendicular to the upper surface of the substrate 201 to form a gate stack structure together with the interlayer insulating layers 120. The gate stack structure may include first to third gate stack structures that are stacked vertically. However, according to embodiments, the number of gate stack structures forming the gate stack structure may be varied. The gate electrodes 130 of the third test element region TR3 may be referred to as test gate electrodes for distinction from the gate electrodes 130 of the chip region CR.

The gate electrodes 130 may include a first upper gate electrode 130U1 forming string select transistors, a second upper gate electrode 130U2 forming an erase transistor, memory gate electrodes 130M forming a plurality of memory cells, and lower gate electrodes 130L forming an erase transistor and a ground select transistor. In this case, the terms ‘upper’ and ‘lower’ may be based on positions during the manufacturing process. The number of memory gate electrodes 130M forming memory cells may be determined depending on the capacity of the semiconductor device 100. According to an example embodiment, the number of the first upper gate electrode 130U1, the second upper gate electrode 130U2, and the lower gate electrodes 130L may be 1 to 4, or more, respectively, and may have the same or different structures as the memory gate electrodes 130M. In some embodiments, the second upper gate electrode 130U2 and/or at least one of the lower gate electrodes 130L may be omitted. Some gate electrodes 130, for example, the memory gate electrodes 130M adjacent to the second upper gate electrode 130U2 or the lower gate electrodes 130L, may be dummy gate electrodes. The first upper gate electrode 130U1 may be disposed to have a relatively thick thickness at the lowermost portion.

The gate electrodes 130 may be disposed to be separated from each other in the Y direction by a first separation region MS that extends continuously in the first region R1 and the second region R2. The gate electrodes 130 are vertically stacked and spaced from each other on the first region R1, and the first gate electrodes may extend from the first region R1 to the second region R2 at different lengths to form step structures in a step shape. The gate electrodes 130 may also be disposed to have step structures in the X direction. However, in example embodiments, the specific forms of the step structures may be variously changed. In some embodiments, the gate electrodes 130 may not form a step structure.

By the step structure, the gate electrodes 130 except for the first upper gate electrode 130U1 may have contact regions in which the upper gate electrode 130 extends longer than the lower gate electrode 130, and are exposed downward from the interlayer insulating layers 120, respectively. The gate electrodes 130 may be respectively connected to cell contact plugs CMC in the contact regions, which are end regions. The gate electrodes 130 may have a form in which the thickness is increased in the contact regions. The first upper gate electrode 130U1 may be connected to a separate contact plug that does not penetrate the first upper gate electrode 130U1.

The gate electrodes 130 may include a conductive material, such as a metal material or a semiconductor material. For example, the gate electrodes 130 except for the first upper gate electrode 130U1 may include tungsten (W), and the first upper gate electrode 130U1 may include polycrystalline silicon. In example embodiments, at least some of the gate electrodes 130 may further include a diffusion barrier, and for example, the diffusion barrier may include tungsten nitride (WN), tantalum nitride (TaN), titanium nitride (TiN), or combinations thereof.

Interlayer insulating layers 120 may be disposed between the gate electrodes 130. The interlayer insulating layers 120 may be alternately stacked with the gate electrodes 130 in a direction, perpendicular to the upper surface of the substrate 201 and extend in the Y direction, similar to the gate electrodes 130. The interlayer insulating layers 120 may include an insulating material such as silicon oxide or silicon nitride. In example embodiments, the thickness of each of the interlayer insulating layers 120 may vary.

The first channel structures CH extend in the Z direction by penetrating through the gate electrodes 130 excluding the first upper gate electrode 130U1 and may be connected to the first source layer 105C. The first channel structures CH form one memory cell string together with the second channel structures SCH, and may be disposed to be spaced apart from each other while forming rows and columns on a plane in the first region R1. The first channel structures CH may be disposed to form a lattice pattern in the X-Y plane or may be disposed in a zigzag shape in one direction. The first channel structures CH have a pillar shape and may have an inclined side surface that becomes narrower as it approaches the first source layer 105C. The first channel structures CH may include expansion regions on upper ends thereof and may be connected to the first source layer 105C in the expansion regions. However, in some embodiments, the first channel structures CH may not include the expansion regions.

The first channel structures CH may include first to third channel portions CH1, CH2 and CH3 that are vertically stacked, respectively. The first to third channel portions CH1, CH2 and CH3 may penetrate the first to third gate stack structures, respectively. The first channel structure CH may have bend portions due to a difference in width at an interface between the first to third channel portions CH1, CH2 and CH3. However, according to embodiments, the number of channel portions stacked along the Z direction in the first channel structure CH may vary.

Each of the first channel structures CH may include a first channel layer disposed within a first channel hole, a first channel dielectric layer, a first channel-buried insulating layer, and a first channel pad. Between the first to third channel portions CH1, CH2 and CH3, the first channel layer, the first channel dielectric layer, and the first channel-buried insulating layer may be connected to each other. The first channel layer may be formed in an annular shape surrounding the first channel-buried insulating layer inside. The upper end of the first channel layer may be connected to the first source layer 105C. The first channel layer may include a semiconductor material such as polycrystalline silicon or single-crystal silicon. The first channel dielectric layer may be disposed between the gate electrodes 130 and the first channel layer. The first channel dielectric layer may include a tunneling layer, a charge storage layer, and a blocking layer sequentially stacked from the first channel layer. The first channel pad may be disposed only at the lower end of the third channel portion CH3. The first channel pad may include, for example, doped polycrystalline silicon.

The second channel structures SCH extend in the Z direction by penetrating through the first upper gate electrode 130U1 and may be connected to the first channel structures CH, respectively. The second channel structures SCH are respectively disposed below the first channel structures CH, and may be disposed shifted in the horizontal direction from the first channel structures CH, but are not limited thereto.

The second channel structures SCH may have a structure corresponding to the first channel structures CH. The second channel structures SCH may each include a second channel layer disposed in a second channel hole, a second channel dielectric layer, a second channel-buried insulating layer, and a second channel pad. The second channel layer may include a connection pad portion horizontally expanded from the upper portion, and may be electrically connected to the first channel layer of the first channel structure CH through the connection pad portion and the first channel pad.

However, in some embodiments, the second channel structure SCH may be omitted. In this case, the first upper gate electrode 130U1 may be stacked together with other gate electrodes 130 and may be penetrated by the first channel structures CH. At least one of the first channel structure CH and the second channel structure SCH may be referred to as a channel structure, or the like, and the channel structure of the third test element region TR3 may be referred to as a test channel structure for distinction thereof from the channel structure of the chip region CR.

The first separation region MS may be disposed to extend along the X direction by penetrating through the gate electrodes 130 except for the first upper gate electrode 130U1. The first separation region MS may also be disposed to penetrate the gate electrodes 130 except for the first upper gate electrode 130U1. A plurality of first separation regions MS may be disposed parallel to each other. The first separation region MS may include an insulating material, for example, silicon oxide, silicon nitride, or silicon oxynitride.

The second separation regions US may extend along the X direction by penetrating through the first upper gate electrode 130U1. The second separation regions US may divide the first upper gate electrode 130U1 in the Y direction. The second separation regions US may include an insulating material, for example, silicon oxide, silicon nitride, or silicon oxynitride.

The first and second source layers 105C and 107 are disposed on the upper ends of the first channel structures CH and may be electrically connected by being in contact with the first channel layers. The first and second source layers 105C and 107 may function as a common source line of the semiconductor device 100. The first and second source layers 105C and 107 may be disposed only in the first region R1 in the chip region CR and may extend onto the dam structure 102 between the first region R1 and the second region R2. The first and second source layers 105C and 107 may include a conductive material. For example, the first source layer 105C may include polycrystalline silicon and the second source layer 107 may include a metal material. However, in example embodiments, the shape of the common source line and the number of layers forming the common source line may be variously changed.

The dam structure 102 may be a layer for the formation process of the first and second source layers 105C and 107, and may be disposed in a region including a boundary between the first region R1 and the second region R2. The dam structure 102 may include an insulating material, for example, silicon oxide.

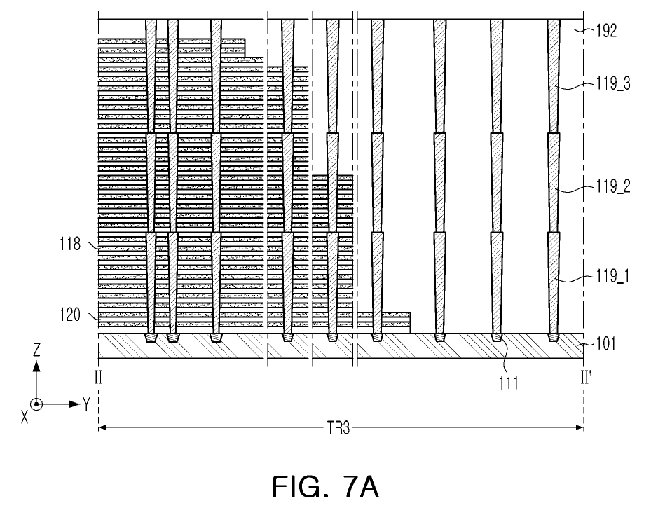

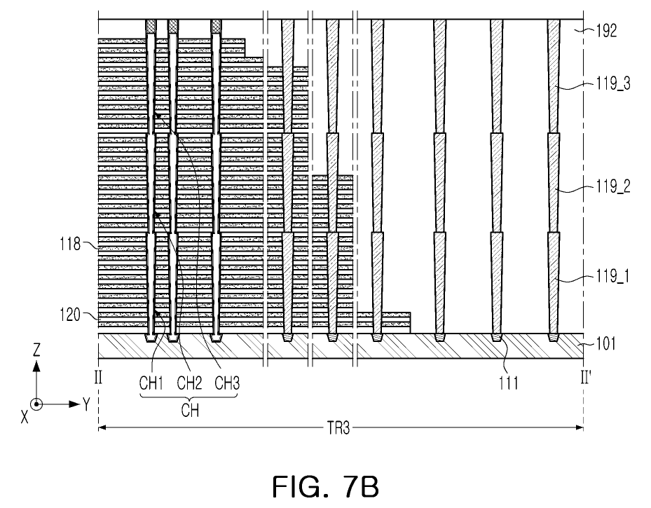

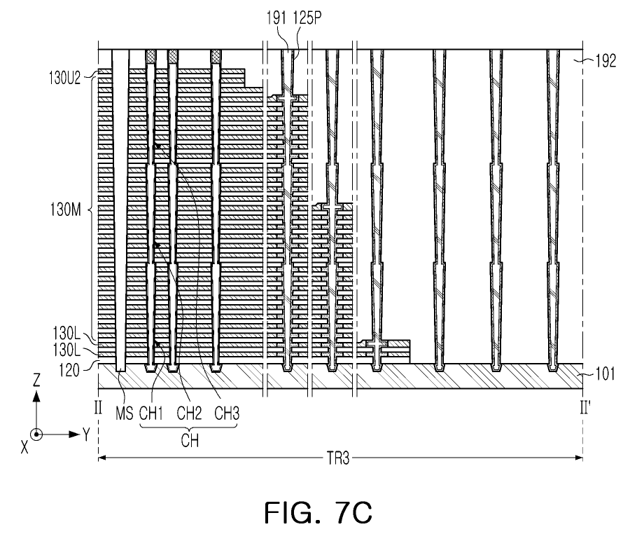

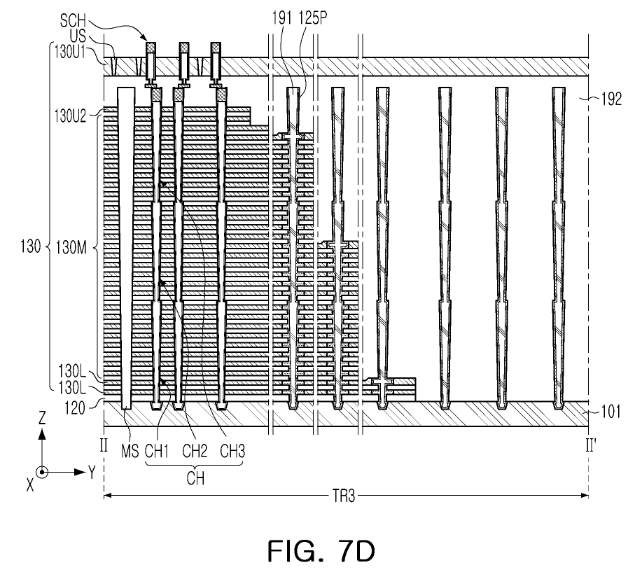

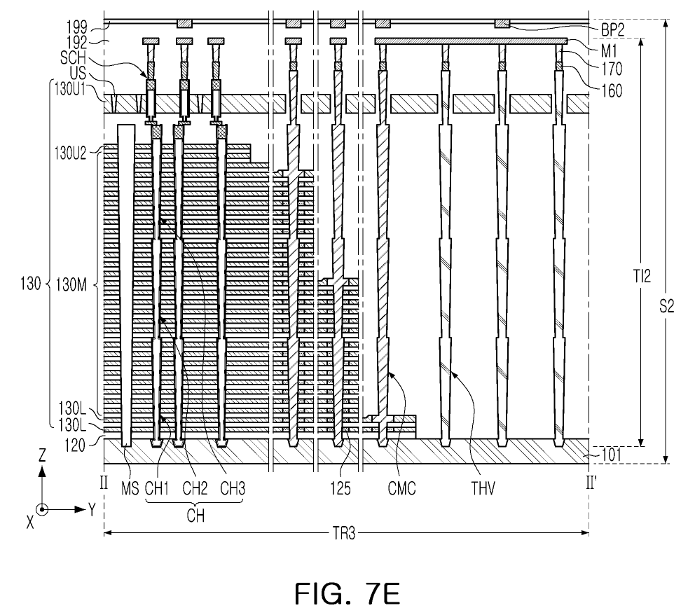

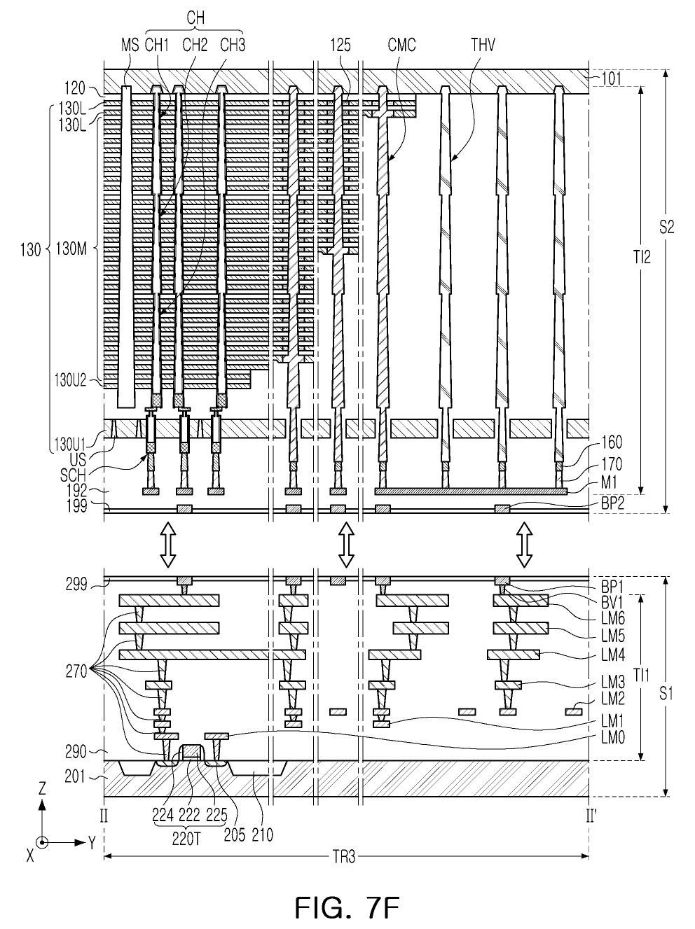

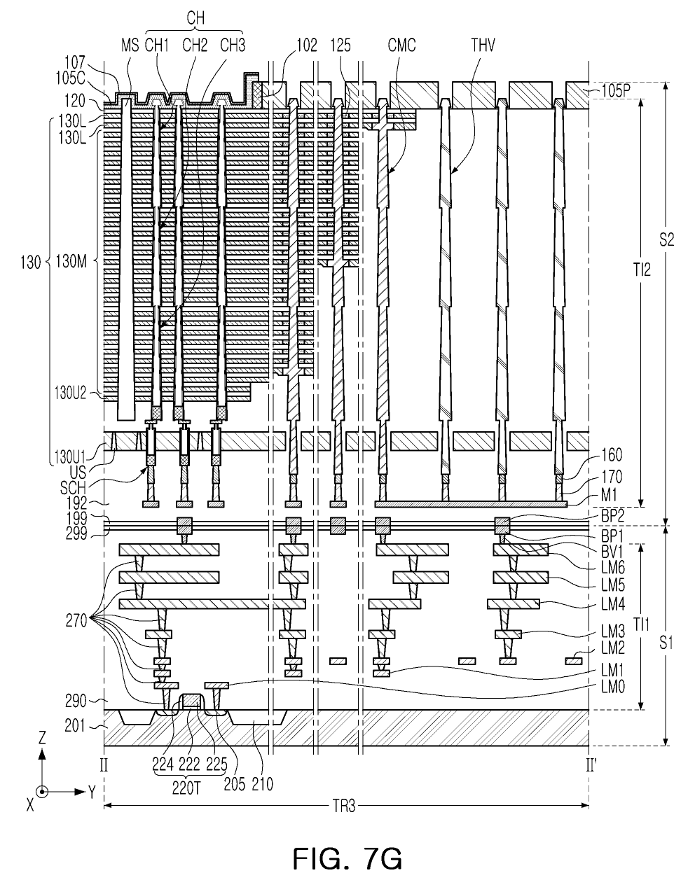

The upper semiconductor layer 105P may be disposed in the second region R2 in the chip region CR, and may include a semiconductor material, for example, silicon. The upper semiconductor layer 105P may be the base substrate 101 (see FIG. 7A) remaining during the manufacturing process of the semiconductor device 100. However, in some embodiments, the upper semiconductor layer 105P may be completely removed and may not remain.

The pad insulating layer 110 is disposed on the upper conductive layers 180, and may include an insulating material. The pad insulating layer 110 may have an opening exposing the upper conductive layer 180 in the third pad region PAD3 of the third test element region TR3.

The first cell region insulating layer 192 may be disposed to cover the lower surfaces and side surfaces of the gate electrodes 130. The second cell region insulating layer 194 may be disposed on the second source layer 107 and the upper semiconductor layer 105P. The first and second cell region insulating layers 192 and 194 may include at least one of an insulating material, for example, silicon oxide, silicon nitride, and silicon carbide, and may be formed of a plurality of insulating layers according to embodiments.

Each of the second interconnection structure IS2 and the second test interconnection structure TI2 may include cell contact plugs CMC, cell through-vias THV, studs 160, lower vias 170, first cell interconnection lines M1, upper vias 150, and upper conductive layers 180. The second interconnection structure IS2 may be electrically connected to the memory cells of the second semiconductor structure S2, and may be referred to as a cell interconnection structure, or the like. The second interconnection structure IS2 and the second test interconnection structure TI2 may be physically and electrically separated from each other. The second test interconnection structure TI2 may be physically and electrically separated from the memory cells and the first test interconnection structure TI1.

The cell contact plugs CMC may be connected to the contact regions of the gate electrodes 130 in the corresponding regions of the second region R2 and the third test element region TR3 of the chip region CR. The cell contact plugs CMC may penetrate the gate electrodes 130 on the contact regions and be connected to the studs 160. The cell contact plugs CMC may be spaced apart from the gate electrodes 130 on the contact regions by contact insulating layers 125. Each of the cell contact plugs CMC may have a form that is horizontally expanded in the contact region. The cell through-vias THV may penetrate the first cell region insulating layer 192 and be connected to the studs 160 and the upper vias 150. The cell contact plugs CMC and the cell through-vias THV may include regions having shapes corresponding to the first channel structures CH.

The studs 160 are connected to the second channel structures SCH, the cell contact plugs CMC, and the cell through-vias THV, and may connect the same to the lower vias 170. The first cell interconnection lines M1 may connect the lower vias 170 and the second bonding vias BV2 in the chip region CR. The first cell interconnection lines M1 may be connected only to the lower vias 170 in the third test element region TR3. The entire lower surfaces of the first cell interconnection lines M1 in the third test element region TR3 may be covered with the first cell region insulating layer 192. The upper vias 150 may connect the second source layer 107 and through-cell vias (THVs) to the upper conductive layers 180.

Each of the cell contact plugs CMC, cell through-vias THV, studs 160, lower vias 170, and upper vias 150 may have a plug shape, and each of the first cell interconnection lines M1 and the upper conductive layers 180 may have a line shape extending in one direction. However, in example embodiments, the number of layers of the interconnection layers forming the second interconnection structure IS2 and the second test interconnection structure TI2, for example, the number of layers and the arrangement of the contact plugs and interconnection lines, may be variously changed.

The cell contact plugs CMC, cell through-vias THV, studs 160, lower vias 170, the first cell interconnection lines M1, upper vias 150, and upper conductive layers 180 may include a metal, for example, tungsten (W), copper (Cu), aluminum (Al), or the like.

In the second substrate structure S2, the cell test element of the test cell array region TCR in the third test element region TR3, for example, the cell test element including the cell contact plug CMC at the far right in FIG. 3B, may be electrically connected to the upper conductive layer 180 of the third pad region PAD3 corresponding to the pad conductive layer through the second test interconnection structure TI2. The pad conductive layer may be exposed upwardly in the third pad region PAD3. Accordingly, the characteristics of the cell test element including the cell contact plug CMC may be tested while being electrically isolated from the circuit test element of the first substrate structure S1.

The second bonding vias BV2, the second bonding pads BP2, and the second bonding insulating layer 199 may form the second bonding structure. The second bonding vias BV2 may connect the first cell interconnection lines M1 and the second bonding pads BP2 in the chip region CR. The second bonding vias BV2 may be disposed only in the chip region CR and may not be disposed in the third test element region TR3. The second interconnection structure IS2 is electrically connected to the first interconnection structure IS1, but since the second bonding vias BV2 are omitted in the third test element region TR3, the second test interconnection structure TI2 may be electrically isolated from the first test interconnection structure TI1. The second test interconnection structure TI2 may be spaced apart from the first test interconnection structure TI1 at the level of the second bonding vias BV2.

The lower surface of the second bonding pads BP2 may form a portion of the lower surface of the second substrate structure S2. The second bonding pads BP2 may be bonded and connected to the first bonding pads BP1 of the first substrate structure S1, and the second bonding insulating layer 199 may be bonded and connected to the first bonding insulating layer 299 of the first substrate structure S1. The second bonding vias BV2 and the second bonding pads BP2 may include a conductive material, for example, copper (Cu). The second bonding insulating layer 199 may include at least one of, for example, SiO, SiN, SiCN, SiOC, SiON, and SiOCN.

The first and second substrate structures S1 and S2 may be bonded by bonding the first bonding pads BP1 and the second bonding pads BP2 and bonding the first bonding insulating layer 299 and the second bonding insulating layer 199. The bonding between the first bonding pads BP2 and the second bonding pads BP2 may be, for example, copper (Cu)-to-copper (Cu) bonding, and the bonding between the first bonding insulating layer 299 and the second bonding insulating layer 199 may be, for example, dielectric-dielectric bonding, such as SiCN-to-SiCN bonding. The first and second substrate structures S1 and S2 may be bonded by hybrid bonding including copper (Cu)-to-copper (Cu) bonding and dielectric-to-dielectric bonding.

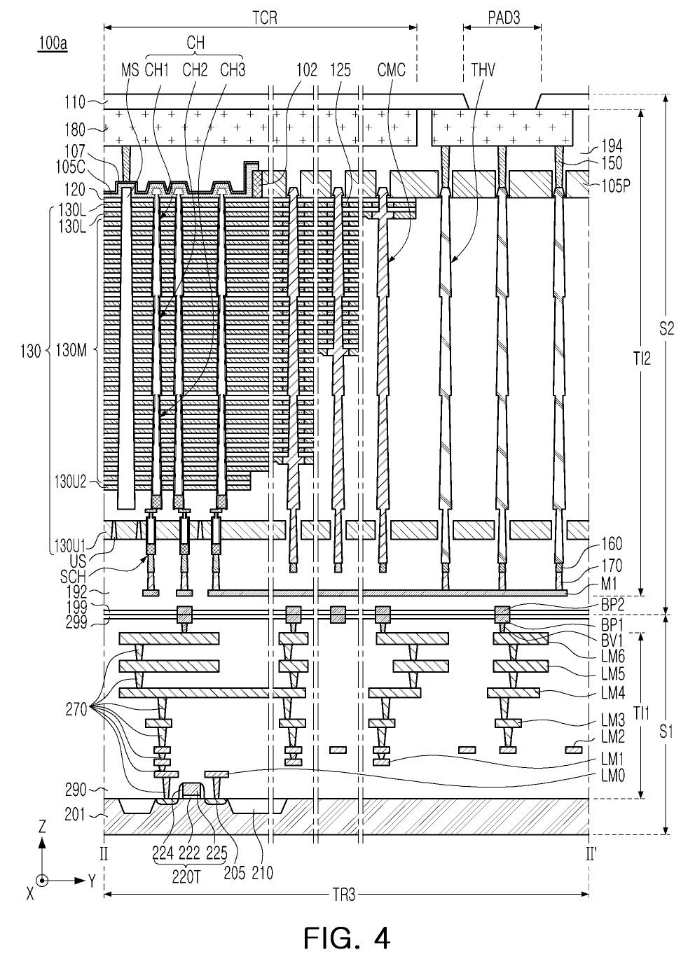

FIG. 4 is a cross-sectional view of a semiconductor device according to example embodiments. FIG. 4 illustrates a region corresponding to FIG. 3B.

Referring to FIG. 4, in the second substrate structure S2 of a semiconductor device 100a, a cell test element of a test cell array region TCR in a third test element region TR3, for example, a cell test element including the first and second channel structures CH and SCH on the far right in FIG. 4, may be electrically connected to an upper conductive layer 180 of a third pad region PAD3 corresponding to a pad conductive layer through a second test interconnection structure TI2. As a result, the characteristics of the cell test element including the first and second channel structures CH and SCH may be tested while being electrically separated from the first substrate structure S1.

In this way, in the test element region of the example embodiments, the configuration of the test cell array region TCR electrically connected to the upper conductive layer 180 of the third pad region PAD3 may be variously changed, and accordingly, the electrical characteristics of the memory cell array structure for testing may be variously evaluated. By measuring the electrical characteristics of the memory cell array structure for testing, the electrical characteristics of the memory cells of the chip region CR (see FIG. 3A) may be predicted.

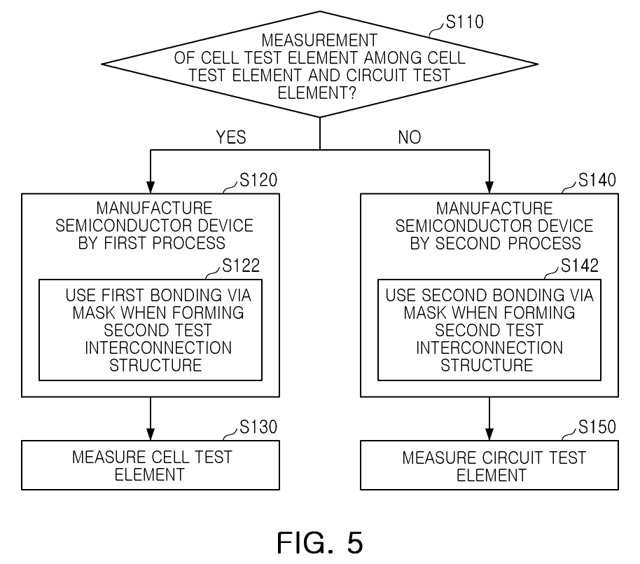

FIG. 5 is a flowchart illustrating a method of measuring a semiconductor device according to example embodiments.

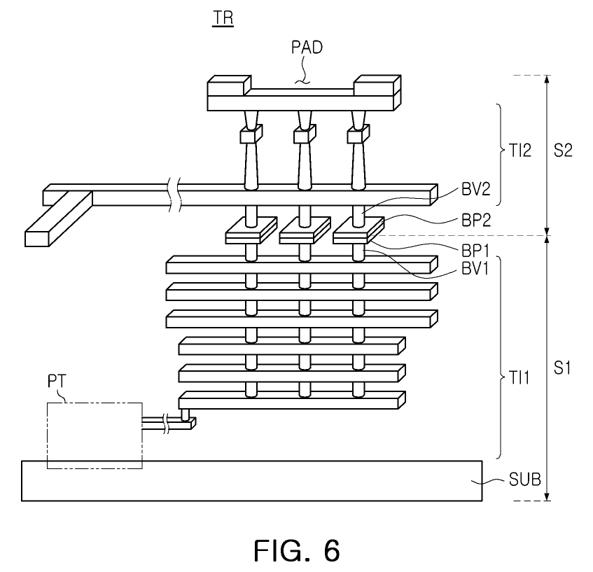

FIG. 6 is a schematic perspective view of a semiconductor device according to example embodiments.

Referring to FIG. 5, the method of measuring a semiconductor device may include an operation (S110) of determining which element among the cell test element and the circuit test element in the test element groups TEG to evaluate, and whether to measure the cell test element CT (see FIG. 2) among the cell test element CT and the circuit test element PT (see FIG. 2). In the case of measuring a cell test element CT, the method may include an operation (S120) of manufacturing a semiconductor device by a first process and an operation (S130) of measuring a cell test element CT. In the case of measuring a circuit test element PT, the method may include an operation (S140) of manufacturing a semiconductor device by a second process and an operation (S150) of measuring a circuit test element PT.

The first process may be a process of manufacturing a semiconductor device including first and second substrate structures S1 and S2 as in the example embodiments of FIGS. 2 to 3B. The first process may be, for example, a full loop process that performs all processes of manufacturing a semiconductor device 100 of FIGS. 3A and 3B. The operation (S120) of manufacturing a semiconductor device by the first process may include an operation (S122) of using a first bonding via mask as a mask for forming second bonding vias BV2 when forming a second test interconnection structure TI2. The first bonding via mask may be a mask in which patterns of second bonding vias BV2 are present only in a chip region CR and no second bonding via BV2 pattern is present in a test element region TR.

In the semiconductor device manufactured by the first process, as described above with reference to FIGS. 2 to 3B, an operation (S130) of measuring an electrical characteristic of a cell test element CT may be performed by applying an electrical signal through a pad region PAD.

The second process may be a process for manufacturing a semiconductor device including first and second substrate structures S1 and S2 such as the example embodiment of FIG. 6 described below. The second process may be a short loop process that performs only some processes among the entire processes for manufacturing the semiconductor device 100 of FIG. 3A and FIG. 3B, for example. The operation (S140) of manufacturing the semiconductor device by the second process may include an operation (S142) of using a second bonding via mask different from the first bonding via mask as a mask for forming second bonding vias BV2 when forming the second test interconnection structure TI2. The second bonding via mask may be a mask having a second bonding via BV2 pattern at least in the test element region TR.

Referring to FIG. 6, the structure of the test element region TR of the semiconductor device manufactured by the second process is schematically illustrated. The test element region TR may correspond to the test element region TR of FIG. 2 and the third test element region TR3 of FIG. 3B. The test element region TR may include first and second substrate structures S1 and S2 that are vertically bonded. The description referring to FIG. 2 may be equally applied to the first substrate structure S1.

The second substrate structure S2 may include a second test interconnection structure TI2 that is disposed on the first substrate structure S1 and is electrically connected to the first test interconnection structure TI1. At least a portion of the second test interconnection structure TI2 may vertically overlap the first test interconnection structure TI1. The second substrate structure S2 may further include second bonding pads BP2 and second bonding vias BV2 that are bonding structures, and a pad region PAD for connection with a test facility.

The second substrate structure S2 of the present embodiment may not include a cell test element CT, unlike the example embodiment of FIG. 2, and may have a relatively small number of layers of contact plugs and interconnection lines forming the second test interconnection structure TI2. In addition, the second substrate structure S2 may further include second bonding vias BV2 electrically connecting the second test interconnection structure TI2 and the second bonding pads BP2, unlike the example embodiment of FIG. 2. Accordingly, an electrical signal applied through the pad region PAD may be applied to a circuit test element PT through the second test interconnection structure TI2, the second bonding vias BV2, the second bonding pads BP2, the first bonding pads BP1, the first bonding vias BV1, and the first test interconnection structure TI1.

In the semiconductor device manufactured by the second process, an operation (S130) of measuring the electrical characteristics of the circuit test element PT may be performed by applying an electrical signal through the pad region PAD.

According to the semiconductor device measuring method, by performing the first process using the first mask and the second process using the second mask as a mask for forming one of the layers electrically connecting the first and second substrate structures S1 and S2, for example, the second bonding via BV2, respectively, the cell test element CT and the circuit test element PT may be respectively evaluated using the same test element region TR. Therefore, the utilization and integration of the test element groups TEG may be improved, and accordingly, the utilization of the scribe lane may be improved.

A method of manufacturing a semiconductor device using the semiconductor device measuring method may include an operation of classifying semiconductor wafers into first wafers and second wafers, an operation of manufacturing a semiconductor device using the first wafers through the first process, and an operation of measuring a cell test element. The method of manufacturing a semiconductor device may further include an operation of manufacturing a semiconductor device using the second wafers through the second process, and an operation of measuring a circuit test element.

FIGS. 7A to 7G are schematic cross-sectional views illustrating a method of manufacturing a semiconductor device according to example embodiments. FIGS. 7A to 7G illustrate cross-sections corresponding to FIG. 3B.

Referring to FIG. 7A, a manufacturing process of a second substrate structure S2 may begin. Unless otherwise stated, the process may be performed simultaneously in the chip region CR of FIG. 3A.

After alternately stacking sacrificial insulating layers 118 and interlayer insulating layers 120 on a base substrate 101, first to third vertical sacrificial layers 119_1, 119_2 and 119_3 may be formed.

The base substrate 101 may be a semiconductor substrate, such as undoped silicon (Si), which is a layer at least partially removed through a subsequent process. After removing a portion of the base substrate 101 from the upper surface, stopper layers 111 may be formed. The stopper layers 111 may include a different material from the base substrate 101, for example, tungsten (W).

Sacrificial insulating layers 118 and interlayer insulating layers 120 may be alternately stacked on the base substrate 101 to sequentially form first to third mold structures. The first to third mold structures may be formed at heights where the first to third channel portions CH1, CH2 and CH3 (see FIG. 3B) are disposed, respectively. The sacrificial insulating layers 118 may be made of a different material from the interlayer insulating layers 120, and may be formed of a material that may be etched with etching selectivity under specific etching conditions with respect to the interlayer insulating layers 120. At the ends of the first to third mold structures, the upper sacrificial insulating layers 118 may be formed to extend shorter than the lower sacrificial insulating layers 118 to include a region having a step structure. After each of the first to third mold structures is formed, the first cell region insulating layer 192 may be formed in part, respectively.

The first vertical sacrificial layers 119_1 may be formed to penetrate the first mold structure and be connected to the stopper layers 111. The first vertical sacrificial layers 119_1 may be formed at positions corresponding to the first channel structures CH1, cell contact plugs CMC, and cell through-vias THV of FIG. 3B. In some embodiments, the first vertical sacrificial layers 119_1 may be further formed at positions corresponding to the first separation region MS. The second and third vertical sacrificial layers 119_2 and 119_3 may be formed to penetrate the second and third mold structures, respectively, in the same manner as the first vertical sacrificial layers 119L. The second vertical sacrificial layers 119_2 may be formed to be connected to the first vertical sacrificial layers 119_1, respectively, and the third vertical sacrificial layers 119_3 may be formed to be connected to the second vertical sacrificial layers 119_2, respectively. The first to third vertical sacrificial layers 119_1, 119_2 and 119_3 may include, for example, polycrystalline silicon, a carbon-based material, or a metal material.

Referring to FIG. 7B, the first channel structures CH may be formed.

First channel holes may be formed by removing some of the first to third vertical sacrificial layers 119_1, 119_2 and 119_3 and removing the exposed stopper layers 111. In each of the first channel holes, at least a portion of the first channel dielectric layer, the first channel layer, and the first channel-buried insulating layer are sequentially deposited, and the first channel pad is formed by removing some of the first channel-buried insulating layer from the top, thereby forming first channel structures CH.

Referring to FIG. 7C, preliminary contact insulating layers 125P and contact sacrificial layers 191 may be formed, and some of the gate electrodes 130 may be formed.

Contact holes may be formed by removing at least a portion of the remaining first to third vertical sacrificial layers 119_1, 119_2 and 119_3 and removing the exposed stopper layers 111. Some of the sacrificial insulating layers 118 and interlayer insulating layers 120 exposed through the contact holes may be removed to form contact tunnel portions extending horizontally from the contact holes. Although not illustrated in detail, the contact tunnel portions may be formed with a relatively short length in the uppermost sacrificial insulating layers 118 and with a relatively long length in the sacrificial insulating layers 118 therebelow. An insulating material may be deposited in the contact holes and the contact tunnel portions to form preliminary contact insulating layers 125P filling the uppermost contact tunnel portions, and contact sacrificial layers 191 filling the contact holes may be further formed. The contact sacrificial layers 191 may include a different material from the preliminary contact insulating layers 125P, and may include, for example, polycrystalline silicon, a carbon-based material, or a metal material.

An opening extending to the substrate 101 by penetrating through the sacrificial insulating layers 118 and the interlayer insulating layers 120 may be formed in the location of the first separation regions MS. Next, an etchant may be supplied through the openings to remove the sacrificial insulating layers 118. The sacrificial insulating layers 118 may be selectively removed with respect to the interlayer insulating layers 120, the first channel structures CH, and the preliminary contact insulating layers, for example, using wet etching.

A conductive material may be deposited in the region where the sacrificial insulating layers 118 have been removed, to form gate electrodes 130. The conductive material may include a metal, polycrystalline silicon, or a metal silicide material. After forming the gate electrodes 130, an insulating material may be deposited in the openings to form the first separation region MS.

Referring to FIG. 7D, a first upper gate electrode 130U1 may be formed, and second channel structures SCH and second separation regions US may be formed.

A nitride layer and a first cell region insulating layer 192 may be further formed on the first channel structures CH, and a first upper gate electrode 130U1 may be formed. The first upper gate electrode 130U1 may include a different material from the other gate electrodes 130, but is not limited thereto. For example, the first upper gate electrode 130U1 may include polycrystalline silicon.

To form the second channel structures SCH, second channel holes extending into the nitride layer by penetrating through the first upper gate electrode 130U1 may be formed first. After partially removing the nitride layer exposed at the bottom surface of the second channel holes to expand the second channel holes, a second channel dielectric layer, a second channel layer, a second channel-buried insulating layer, and a second channel pad are sequentially formed within the second channel holes to form a second channel structure SCH.

The second separation regions US may be formed to penetrate the first upper gate electrode 130U1. The second separation regions US may be formed by forming openings penetrating the first upper gate electrode 130U1 and depositing an insulating material in the openings.

Referring to FIG. 7E, a portion of the second test interconnection structure TI2 and second bonding pads BP2 may be formed.

To form cell contact plugs CMC and cell through-hole vias THV, openings may be formed to expose contact sacrificial layers 191. After removing the contact sacrificial layers 191 exposed through the openings and partially removing the preliminary contact insulating layers 172P, a conductive material may be deposited to form cell contact plugs CMC and cell through-vias THV. At this time, the preliminary contact insulating layers 125P may be completely removed from the uppermost gate electrodes 130, and may remain therebelow to form contact insulating layers 125.

Studs 160, lower vias 170, and first cell interconnection lines M1 may be sequentially formed on the second channel structures SCH, the cell contact plugs CMC, and the cell through-vias THV. The second bonding pads BP2 may be formed vertically spaced apart from the first cell interconnection lines M1. In the chip region CR (see FIG. 3A), second bonding vias BV2 (see FIG. 3A) may be further formed on the first cell interconnection lines M1 before the formation of the second bonding pads BP2.

Referring to FIG. 7F, a first substrate structure S1 and a second substrate structure S2 may be bonded.

The first substrate structure S1 may be prepared by forming a test circuit gate structure 220T, a first test interconnection structure TI1, and a first bonding structure on a substrate 201.

Element isolation layers 210 may be formed in the substrate 201, and a circuit gate dielectric layer 222 and a circuit gate electrode 225 may be sequentially formed on the substrate 201. The element isolation layers 210 may be formed, for example, by a shallow trench isolation (STI) process. The circuit gate dielectric layer 222 may be formed of silicon oxide, and the circuit gate electrode 225 may be formed of at least one of polycrystalline silicon or a metal silicide layer, but is not limited thereto. Next, a spacer layer 224 and impurity regions 205 may be formed on both side walls of the circuit gate dielectric layer 222 and the circuit gate electrode 225. According to embodiments, the spacer layer 224 may be formed of a plurality of layers. The impurity regions 205 may be formed by performing an ion implantation process. In the chip region CR (see FIG. 3A), the circuit gate structures 220 (see FIG. 3A) may be formed together with the test circuit gate structure 220T.

The circuit contact plugs 270 of the first test interconnection structure TI1 and the first bonding vias BV1 of the first bonding structure may be formed by forming a portion of the surrounding insulating layer 290, then etching and removing a portion of the surrounding insulating layer 290, and filling in a conductive material. The circuit interconnection lines LM0, LM1, LM2, LM3, LM4, LM5 and LM6 of the first test interconnection structure TI1 and the first bonding pads BP1 of the first bonding structure may be formed, for example, by depositing a conductive material and then patterning it. The first bonding pads BP1 may be formed so that the upper surface is exposed through the first bonding insulating layer 299. In the chip region CR, the first interconnection structure IS1 (see FIG. 3A) may be formed together with the first test interconnection structure TI1.

The peripheral insulating layer 290 may be formed of a plurality of insulating layers. The peripheral insulating layer 290 may be partially formed in respective operations of forming the first test interconnection structure TI1 and the first bonding structure. In this operation, the first semiconductor structure S1 may be prepared.

The first substrate structure S1 and the second substrate structure S2 may be connected by bonding the first bonding pads BP1 and the second bonding pads BP2 by annealing and/or applying pressure. At the same time, the first bonding insulating layer 299 and the second bonding insulating layer 199 may also be bonded. The second substrate structure S2 may be disposed face down on the first substrate structure S1 so that the second bonding pads BP2 face downward, and then bonding may be performed.

Referring to FIG. 7G, on the bonding structure of the first and second substrate structures S1 and S2, a portion of the base substrate 101 may be removed, and the first and second source layers 105C and 107 may be formed.

After the dam structure 102 is first formed, the base substrate 101 may be removed at least on the first channel structures CH. For example, the base substrate 101 may be partially removed from the upper surface by a polishing process such as a grinding process, and the remaining portion may be removed by an etching process such as wet etching. On the upper ends of the first channel structures CH exposed after the base substrate 101 is removed, the first channel dielectric layers may be removed and the first channel layers may thus be exposed. The first and second source layers 105C and 107 may be sequentially formed on the upper ends of the first channel structures CH and the upper end of the separation region MS.

The remaining base substrate 101 may form an upper semiconductor layer 105P. The upper semiconductor layer 105P may be patterned when a portion of the base substrate 101 is removed or patterned in a separate process to expose the upper ends of the cell contact plugs CMC and the cell through-vias THV.

Next, referring to FIG. 3B together, upper vias 150 and upper conductive layers 180 may be formed.

A second cell region insulating layer 194 may be formed on the first and second source layers 105C and 107 and the upper semiconductor layer 105P. The second cell region insulating layer 194 may be partially removed and a conductive material may be deposited to form upper vias 150. The upper vias 150 may be connected to the second source layer 107 and cell through-vias THV. The upper conductive layers 180 may be formed on the upper vias 150, and the pad insulating layer 110 may be formed on the upper conductive layers 180. As a result, the semiconductor device 100 of FIG. 3A and FIG. 3B may be manufactured.

The processes described above with reference to FIGS. 7A to 7G and FIG. 3B may correspond to the first process of FIG. 5. In the second process of FIG. 5, the process of forming the first substrate structure S1 may be the same as in the first process, but the process of forming the second substrate structure S2 may be different from in the first process. For example, among the processes of forming the second substrate structure S2, only some processes of the second test interconnection structure TI2 may be performed in the same manner, so that the second test interconnection structure TI2 may be formed with relatively fewer layers. In some embodiments, in the second process, the process of forming the first substrate structure S1 may also be formed to have the first test interconnection structure TI1 with relatively fewer layers, unlike in the first process.

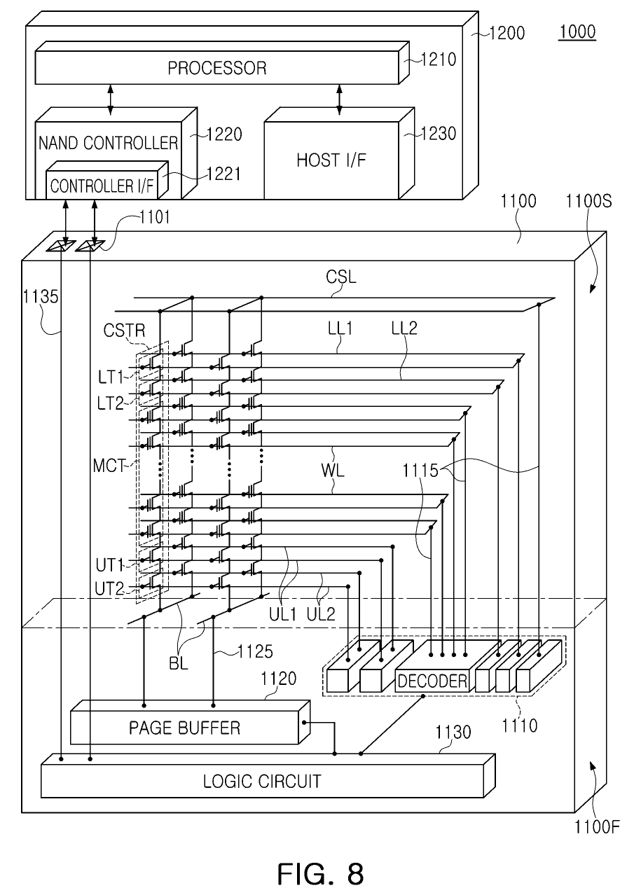

FIG. 8 is a diagram schematically illustrating a data storage system including a semiconductor device according to example embodiments.

Referring to FIG. 8, the data storage system 1000 may include a semiconductor device 1100 and a controller 1200 electrically connected to the semiconductor device 1100. The data storage system 1000 may be a storage device including one or more semiconductor devices 1100 or an electronic device including the storage device. For example, the data storage system 1000 may be a solid state drive device (SSD), a Universal Serial Bus (USB), a computing system, a medical device, or a communication device including one or more semiconductor devices 1100.

The semiconductor device 1100 may be a nonvolatile memory device, and may be, for example, a NAND flash memory device described above with reference to FIGS. 1 to 4. The semiconductor device 1100 may include a first structure 1100F and a second structure 1100S on the first structure 1100F. In example embodiments, the first structure 1100F may be disposed next to the second structure 1100S. The first structure 1100F may be a peripheral circuit structure including a decoder circuit 1110, a page buffer 1120, and a logic circuit 1130. The second structure 1100S may be a memory cell structure including a bit line BL, a common source line CSL, word lines WL, first and second upper gate lines UL1 and UL2, first and second lower gate lines LL1 and LL2, and memory cell strings CSTR between the bit line BL and the common source line CSL.

In the second structure 1100S, each memory cell string CSTR may include lower transistors LT1 and LT2 adjacent to a common source line CSL, upper transistors UT1 and UT2 adjacent to a bit line BL, and a plurality of memory cell transistors MCT disposed between the lower transistors LT1 and LT2 and the upper transistors UT1 and UT2. The number of lower transistors LT1 and LT2 and the number of upper transistors UT1 and UT2 may vary depending on embodiments.

In example embodiments, the upper transistors UT1 and UT2 may include string select transistors, and the lower transistors LT1 and LT2 may include ground select transistors. The lower gate lines LL1 and LL2 may be gate electrodes of the lower transistors LT1 and LT2, respectively. The word lines WL may be gate electrodes of the memory cell transistors MCT, and the upper gate lines UL1 and UL2 may be gate electrodes of the upper transistors UT1 and UT2, respectively.

In example embodiments, the lower transistors LT1 and LT2 may include a lower erase control transistor LT1 and a ground select transistor LT2 that are connected in series. The upper transistors UT1 and UT2 may include a string select transistor UT1 and an upper erase control transistor UT2 that are connected in series. At least one of the lower erase control transistor LT1 and the upper erase control transistor UT2 may be used for an erase operation that erases data stored in the memory cell transistors MCT by utilizing the GIDL phenomenon.

The common source line CSL, the first and second lower gate lines LL1 and LL2, the word lines WL, and the first and second upper gate lines UL1 and UL2 may be electrically connected to the decoder circuit 1110 through first connection interconnections 1115 extending from the first structure 1100F to the second structure 1100S. The bit lines BL may be electrically connected to the page buffer 1120 through second connection interconnections 1125 extending from the first structure 1100F to the second structure 1100S.

In the first structure 1100F, the decoder circuit 1110 and the page buffer 1120 may perform a control operation for at least one selected memory cell transistor among the plurality of memory cell transistors MCT. The decoder circuit 1110 and the page buffer 1120 may be controlled by the logic circuit 1130. The semiconductor device 1100 may communicate with the controller 1200 through an input/output pad 1101 that is electrically connected to the logic circuit 1130. The input/output pad 1101 may be electrically connected to the logic circuit 1130 through an input/output interconnection 1135 that extends from the first structure 1100F to the second structure 1100S.

The controller 1200 may include a processor 1210, a NAND controller 1220, and a host interface 1230. According to embodiments, the data storage system 1000 may include a plurality of semiconductor devices 1100, and in this case, the controller 1200 may control the plurality of semiconductor devices 1100.

The processor 1210 may control the overall operation of the data storage system 1000 including the controller 1200. The processor 1210 may operate according to a predetermined firmware and may control the NAND controller 1220 to access the semiconductor device 1100. The NAND controller 1220 may include a controller interface 1221 that processes communication with the semiconductor device 1100. Through the controller interface 1221, a control command for controlling the semiconductor device 1100, data to be written to the memory cell transistors MCT of the semiconductor device 1100, data to be read from the memory cell transistors MCT of the semiconductor device 1100, or the like may be transmitted. The host interface 1230 may provide a communication function between the data storage system 1000 and an external host. When receiving a control command from an external host through the host interface 1230, the processor 1210 may control the semiconductor device 1100 in response to the control command.

As set forth above, by disposing a circuit test element region of a first substrate structure and a cell test element region of a second substrate structure to overlap each other vertically, a semiconductor device having improved utilization of a scribe lane and a data storage system including the same may be provided.

While example embodiments have been illustrated and described above, it will be apparent to those skilled in the art that modifications and variations could be made without departing from the scope of the present inventive concept as defined by the appended claims.

What is claimed is:

1. A semiconductor device comprising:
a first substrate structure including a substrate, circuit elements on the substrate in a chip region, a circuit interconnection structure on the circuit elements, a circuit test element in a test element region, spaced from the chip region, a first test interconnection structure in the test element region and electrically connected to the circuit test element, and first bonding pads on the circuit interconnection structure and the first test interconnection structure; and
a second substrate structure on the first substrate structure,
wherein the second substrate structure includes:
gate electrodes stacked while being spaced apart from each other in a first direction, perpendicular to an upper surface of the substrate in the chip region;
a channel structure penetrating the gate electrodes;
a cell interconnection structure electrically connected to the channel structure and the gate electrodes;
a cell test element in the test element region;
a second test interconnection structure in the test element region and electrically connected to the cell test element, and electrically isolated from the first test interconnection structure; and
second bonding pads below the cell interconnection structure and the second test interconnection structure and bonded to the first bonding pads respectively.

2. The semiconductor device of claim 1, wherein the second test interconnection structure is spaced apart from the second bonding pads in the first direction and electrically isolated therefrom.

3. The semiconductor device of claim 2, wherein each of the cell interconnection structure and the second test interconnection structure includes cell interconnection lines on the second bonding pads, and
the cell interconnection structure further includes second bonding vias connecting the cell interconnection lines and the second bonding pads.

4. The semiconductor device of claim 3, wherein the second substrate structure further includes a cell region insulating layer on the gate electrodes and the cell test element, and
in the second test interconnection structure, entire lower surfaces of the cell interconnection lines are covered with the cell region insulating layer.

5. The semiconductor device of claim 1, wherein the cell test element includes test gate electrodes corresponding to the gate electrodes and a test channel structure extending vertically along the first direction.

6. The semiconductor device of claim 5, wherein the second test interconnection structure includes a pad conductive layer exposed upward, and
the pad conductive layer is electrically connected to one of the test gate electrodes or the test channel structure.

7. The semiconductor device of claim 1, wherein a portion of the first bonding pads is electrically connected to the first test interconnection structure.

8. The semiconductor device of claim 7, wherein a portion of the second bonding pads is electrically connected to the first test interconnection structure.

9. The semiconductor device of claim 1, wherein the chip region is a memory cell region where memory cells are disposed, and the test element region is a scribe lane region.

10. The semiconductor device of claim 1, wherein the circuit element includes a circuit gate electrode on the substrate and circuit source/drain regions within the substrate, and
the circuit test element includes a test circuit gate electrode and test circuit source/drain regions, disposed to correspond to the circuit element.

11. The semiconductor device of claim 10, wherein the first test interconnection structure is electrically connected to one of the test circuit source/drain regions or the test circuit gate electrode.

12. The semiconductor device of claim 1, wherein the second test interconnection structure overlaps the first test interconnection structure in the first direction.

13. The semiconductor device of claim 1, wherein the second test interconnection structure is electrically isolated from the cell interconnection structure.

14. A semiconductor device comprising:
a first substrate structure including a substrate, a circuit test element on the substrate, and a first test interconnection structure electrically connected to the circuit test element; and
a second substrate structure on the first substrate structure, the second substrate structure including a cell test element including test gate electrodes spaced apart from each other and stacked in a first direction, perpendicular to an upper surface of the substrate and a test channel structure penetrating the test gate electrodes, and a second test interconnection structure electrically connected to one of the test gate electrodes and the test channel structure,
wherein the second test interconnection structure overlaps the first test interconnection structure in the first direction and is spaced apart from the first test interconnection structure.

15. The semiconductor device of claim 14, wherein the second test interconnection structure is electrically isolated from the first test interconnection structure.

16. The semiconductor device of claim 14, wherein the cell test element is electrically isolated from the circuit test element.

17. The semiconductor device of claim 14, wherein the second substrate structure further includes memory cells spaced apart from the cell test element, and
the cell test element has a structure corresponding to the memory cells.

18. The semiconductor device of claim 17, wherein the first substrate structure further includes circuit elements spaced apart from the circuit test element and configured to drive the memory cells, and
the circuit test element has a structure corresponding to the circuit elements.

19. A data storage system comprising:
a semiconductor storage device including a first substrate structure including a substrate and circuit elements on the substrate, a second substrate structure on the first substrate structure, and an input/output pad electrically connected to the circuit elements; and
a controller electrically connected to the semiconductor storage device through the input/output pad and configured to control the semiconductor storage device,
wherein the first substrate structure further includes a circuit test structure disposed to be spaced apart from the circuit elements,
the second substrate structure includes memory cells, vias below the memory cells and electrically connected to the memory cells, and a cell test structure spaced apart from the memory cells to one side, and
the cell test structure is stacked on the circuit test structure and spaced apart from the circuit test structure at a level of the vias.

20. The data storage system of claim 19, wherein the cell test structure is electrically isolated from the memory cells.
